(19) United States
(12) Patent Application Publication
(10) Pub. No.: US 2016/0042770 A1
(43) Pub. Date: Feb. 11, 2016

(54) SEMICONDUCTOR MEMORY APPARATUS

(71) Applicant: SK hynix Inc., Icheon-si Gyeonggi-do (KR)

(72) Inventor: Dong Keun KIM, Icheon-si Gyeonggi-do (KR)

(21) Appl. No.: 14/553,184

(22) Filed: Nov. 25, 2014

(30) Foreign Application Priority Data
Aug. 8, 2014 (KR) 10-2014-0102525

(51) Int. Cl. G11C 5/10; G11C 7/06

(52) U.S. Cl. CPC G11C 5/10; G11C 7/062

(57) ABSTRACT

A semiconductor memory apparatus includes a first memory cell electrically coupled to a word line and a bit line; a second memory cell electrically coupled to the word line and a bit line bar; a sense amplifier electrically coupled to the bit line and the bit line bar; and a switching unit configured to electrically couple the bit line and the bit line bar to an input/output line and an input/output line bar in response to a column select signal.

### CROSS-REFERENCES TO RELATED APPLICATION

The present application claims priority under 35 U.S.C. §119(a) to Korean application number 10-2014-0102525, filed on Aug. 8, 2014, in the Korean Intellectual Property Office, which is incorporated herein by reference in its entirety.

### BACKGROUND

1. Technical Field

Various embodiments generally relate to a semiconductor integrated circuit, and more particularly, to a semiconductor memory apparatus.

2. Related Art

Semiconductor memory apparatuses are configured to store data and output stored data. Semiconductor memory apparatuses are classified into a nonvolatile semiconductor memory apparatus and a volatile semiconductor memory apparatus according to a scheme in which data are stored and retained.

The volatile semiconductor memory apparatus performs a refresh operation to retain stored data, and the nonvolatile semiconductor memory apparatus does not need a separate operation (such as the refresh operation) to retain stored data.

Among volatile semiconductor memory apparatuses, there is a semiconductor memory apparatus in which charges are charged into or discharged from a capacitor according to data to be stored and which includes a circuit (for example, a sense amplifier) for determining the amount of charges of the capacitor.

As semiconductor memory apparatuses trend toward miniaturization and low power consumption, the size of a capacitor is being decreased, and an amount of charges to be charged into the capacitor is also being decreased. Under this situation, a circuit capable of determining the decreased amount of charges of the capacitor is being developed as well.

### SUMMARY

In an embodiment, a semiconductor memory apparatus may include a first memory cell electrically coupled to a word line and a bit line. The semiconductor memory apparatus may also include a second memory cell electrically coupled to the word line and a bit line bar. Further, the semiconductor memory apparatus may include a sense amplifier electrically coupled to the bit line and the bit line bar. In addition, the semiconductor memory apparatus may include a switching unit configured to electrically couple the bit line and the bit line bar to an input/output line and an input/output line bar in response to a column select signal.

In an embodiment, a semiconductor memory apparatus may include a first memory cell including a first capacitor electrically coupled to a first bit line when a word line is enabled. The semiconductor memory apparatus may also include a second memory cell including a second capacitor electrically coupled to a first bit line bar when the word line is enabled. In addition, the semiconductor memory apparatus may include a third memory cell including a third capacitor electrically coupled to a second bit line when the word line is enabled. Further, the semiconductor memory apparatus may include a fourth memory cell including a fourth capacitor electrically coupled to a second bit line bar when the word line is enabled. The semiconductor memory apparatus may also include a first sense amplifier electrically coupled to the first bit line and the first bit line bar. In addition, the semiconductor memory apparatus may include a second sense amplifier electrically coupled to the second bit line and the second bit line bar. Further, the semiconductor memory apparatus may include a first switching unit configured to electrically couple the first bit line and a first input/output line and electrically couple the first bit line bar and a first input/output line bar in response to a first column select signal. The semiconductor memory apparatus may also include a second switching unit configured to electrically couple the second bit line and a second input/output line and electrically couple the second bit line bar and a second input/output line bar in response to a second column select signal.

In an embodiment, a semiconductor memory apparatus may include a plurality of memory cells electrically coupled to a word line. The semiconductor memory apparatus may also include a plurality of bit lines electrically coupled to the plurality of memory cells. The semiconductor memory apparatus may also include a switching unit configured to electrically couple a pair of bit lines of the plurality of bit lines with a pair of input/output lines in response to a column select signal. Further, the semiconductor memory apparatus may include a sense amplifier configured to sense and amplify a voltage difference of the pair of bit lines, wherein a pair of memory cells are selected among the plurality of memory cells in response to the word line and the column select signal, different data are stored in the selected pair of memory cells, and the pair of memory cells are configured to output different data.

### BRIEF DESCRIPTION OF THE DRAWINGS

FIG. 1 is a configuration diagram illustrating a representation of an example of a semiconductor memory apparatus in accordance with an embodiment.

FIG. 2 is a representation of an example of an operation characteristic diagram of the semiconductor memory apparatus in accordance with an embodiment.

FIG. 3 is a configuration diagram illustrating a representation of an example of a semiconductor memory apparatus in accordance with an embodiment.

FIG. 4 is a configuration diagram illustrating a representation of an example of a semiconductor memory apparatus in accordance with an embodiment.

FIG. 5 illustrates a block diagram of a system employing a memory controller circuit in accordance with an embodiment of the invention.

### DETAILED DESCRIPTION

Hereinafter, a semiconductor memory apparatus will be described below with reference to the accompanying drawings through various embodiments.

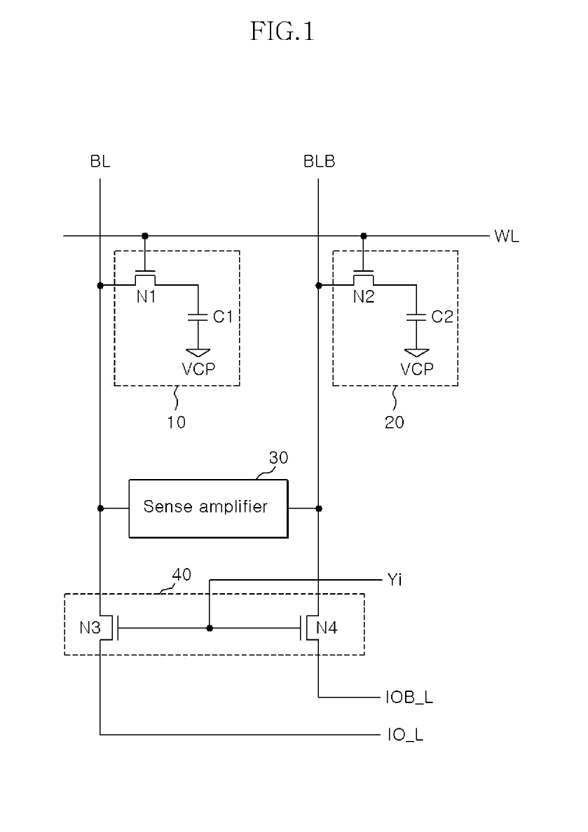

Referring to FIG. 1, a semiconductor memory apparatus includes a first memory cell 10, a second memory cell 20, a sense amplifier 30, and a switching unit 40.

The first memory cell 10 is electrically coupled to a word line WL and a bit line BL.

The second memory cell 20 is also electrically coupled to the word line WL and a bit line bar BLB.

The sense amplifier 30 is also electrically coupled to the bit line BL and the bit line bar BLB.

The switching unit 40 electrically couples or decouples the bit line BL and an input/output line IO_L and electrically couples or decouples the bit line bar BLB and an input/output line bar IOB_L in response to a column select signal Yi.

The first memory cell 10 includes a first transistor N1 and a first capacitor C1. The first transistor N1 has the gate to which the word line WL is electrically coupled, and the drain and the source to which the bit line BL and one end of the first capacitor C1 are electrically coupled. The first capacitor C1 has one end to which the first transistor N1 is electrically coupled and the other end which is applied with a cell plate voltage VCP.

In the first memory cell 10, if the word line WL is enabled, the charges of the first capacitor C1 are transferred to the bit line BL. In the alternative, the charges of the bit line BL are transferred to the first capacitor C1. In detail, if the word line WL is enabled, the first transistor N1 is turned on. If the first transistor N1 is turned on, the first capacitor C1 and the bit line BL are electrically coupled. If the first capacitor C1 is electrically coupled with the bit line BL, the charges of the first capacitor C1 are transferred to the bit line BL. Alternatively, the charges of the bit line BL are transferred to the first capacitor C1. Charges are transferred from the bit line BL to the first capacitor C1 where the charge amount of the bit line BL is larger than the charge amount of the first capacitor C1. In addition, the bit line BL is transferred with charges from the first capacitor C1 where the charge amount of the bit line BL is smaller than the charge amount of the first capacitor C1.

The second memory cell 20 includes a second transistor N2 and a second capacitor C2. The second transistor N2 has the gate to which the word line WL is electrically coupled, and the drain and the source to which the bit line bar BLB and one end of the second capacitor C2 are electrically coupled. The second capacitor C2 has one end to which the second transistor N2 is electrically coupled, and the other end which is applied with the cell plate voltage VCP.

In the second memory cell 20, if the word line WL is enabled, the charges of the second capacitor C2 are transferred to the bit line bar BLB, or the charges of the bit line bar BLB are transferred to the second capacitor C2. In detail, if the word line WL is enabled, the second transistor N2 is turned on. If the second transistor N2 is turned on, the second capacitor C2 and the bit line bar BLB are electrically coupled. If the second capacitor C2 is electrically coupled with the bit line bar BLB, the charges of the second capacitor C2 are transferred to the bit line bar BLB. In the alternative, the charges of the bit line bar BLB are transferred to the second capacitor C2. Charges are transferred from the bit line bar BLB to the second capacitor C2 where the charge amount of the bit line bar BLB is larger than the charge amount of the second capacitor C2. Further, the bit line bar BLB is transferred with charges from the second capacitor C2 where the charge amount of the bit line bar BLB is smaller than the charge amount of the second capacitor C2.

The sense amplifier 30 is electrically coupled to the bit line BL and the bit line bar BLB. The sense amplifier 30 also senses and amplifies the difference between the voltage level of the bit line BL and the voltage level of the bit line bar BLB. For example, where the voltage level of the bit line BL is higher than the voltage level of the bit line bar BLB, the sense amplifier 30 raises the voltage level of the bit line BL and lowers the voltage level of the bit line bar BLB. Where the voltage level of the bit line BL is lower than the voltage level of the bit line bar BLB, the sense amplifier 30 lowers the voltage level of the bit line BL and raises the voltage level of the bit line bar BLB.

The switching unit 40 includes third and fourth transistors N3 and N4. The third transistor N3 has the gate inputted with the column select signal Yi, and the drain and the source to which the bit line BL and the input/output line IO_L are respectively electrically coupled. The fourth transistor N4 has the gate inputted with the column select signal Yi, and the drain and the source to which the bit line bar BLB and the input/output line bar IOB_L are respectively electrically coupled.

The third and fourth transistors N3 and N4 are turned on when the column select signal Yi is enabled. More specifically, if the column select signal Yi is enabled, the switching unit 40 electrically couples the bit line BL and the input/output line IO_L and electrically couples the bit line bar BLB and the input/output line bar IOB_L. The third and fourth transistors N3 and N4 are turned off when the column select signal Yi is disabled. In particular, if the column select signal Yi is disabled, the switching unit 40 electrically decouples the bit line BL and the input/output line IO_L and electrically decouples the bit line bar BLB and the input/output line bar IOB_L.

The semiconductor memory apparatus in accordance with the embodiment, configured as mentioned above, operates as described below.

A write operation, or an operation of storing data in memory cells will be described with reference to FIG. 1.

In the write operation, data with different levels are transferred to the input/output line IO_L and the input/output line bar IOB_L from an exterior of the semiconductor memory apparatus. For example, if high level data is transferred to the input/output line IO_L, low level data is transferred to the input/output line bar IOB_L. Conversely, if low level data is transferred to the input/output line IO_L, high level data is transferred to the input/output line bar IOB_L.

As the column select signal Yi is enabled, the switching unit 40 electrically couples the input/output line IO_L and the bit line BL. Further, as the column select signal Yi is enabled, the switching unit 40 electrically couples the input/output line bar IOB_L and the bit line bar BLB.

If the input/output line IO_L and the bit line BL are electrically coupled, the data of the input/output line IO_L is transferred to the bit line BL. If the input/output line bar IOB_L and the bit line bar BLB are electrically coupled, the data of the input/output line bar IOB_L is transferred to the bit line bar BLB.

If the word line WL is enabled, the data of the bit line BL is stored in the first memory cell 10. If the word line WL is enabled, the data of the bit line bar BLB is stored in the second memory cell 20. More specifically, if the word line WL is enabled, the first capacitor C1 of the first memory cell 10 is electrically coupled to the bit line BL. In addition, the second capacitor C2 of the second memory cell 20 is electrically coupled to the bit line bar BLB. If the first capacitor C1 is electrically coupled to the bit line BL, the data of the bit line BL, that is, the charges of the bit line BL may be charged into the first capacitor C1. If the second capacitor C2 is electrically coupled to the bit line bar BLB, the data of the bit line bar BLB, that is, the charges of the bit line bar BLB may be charged into the second capacitor C2. If the charge amount of the bit line BL is smaller than the charge amount of the first capacitor C1, the charges of the first capacitor C1 are discharged to the bit line BL. If the charge amount of the bit line bar BLB is smaller than the charge amount of the second capacitor C2, the charges of the second capacitor C2 are discharged to the bit line bar BLB. In contrast, if the charge amount of the bit line BL is larger than the charge amount of the first capacitor C1, the charges of the bit line BL are discharged to the first capacitor C1. If the charge amount of the bit line bar BLB is larger than the charge amount of the second capacitor C2, the charges of the bit line bar BLB are discharged to the second capacitor C2.

As a result, in the write operation where data are stored in the first and second memory cells 10 and 20, data with different levels are transferred to the input/output line IO_L and the input/output line bar IOB_L. The data with different levels are transferred to the bit line BL and the bit line bar BLB. In addition, the first and second memory cells 10 and 20 store the data with different levels.

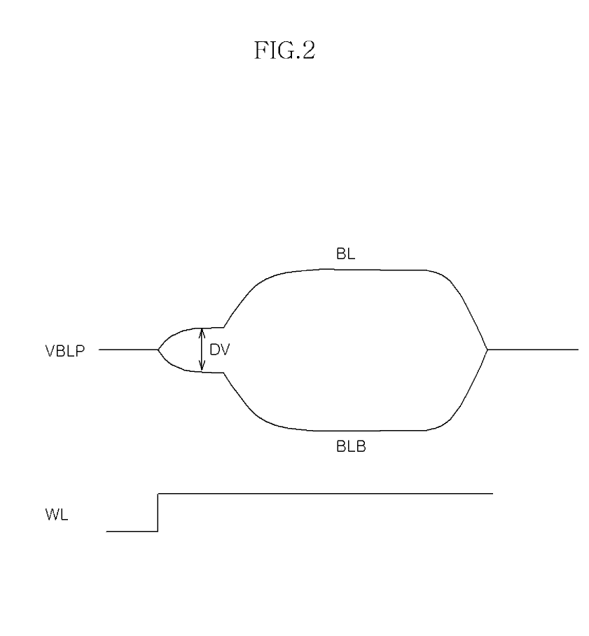

A read operation, or, an operation of outputting data from memory cells will be described with reference to FIGS. 1 and 2. The bit line BL and the bit line bar BLB are in a state in which they are precharged to the voltage level of a bit line precharge voltage VBLP.

As described above, data with different levels are stored in the first and second memory cells 10 and 20. For example, if high level data is stored in the first memory cell 10, low level data is stored in the second memory cell 20. In contrast, if low level data is stored in the first memory cell 10, high level data is stored in the second memory cell 20.

If the word line WL is enabled, the first capacitor C1 is electrically coupled to the bit line BL. If the word line WL is enabled, the second capacitor C2 is electrically coupled to the bit line bar BLB.

Where the first capacitor C1 and the bit line BL are electrically coupled, if the charge amount of the first capacitor C1 is larger than the charge amount of the bit line BL, that is, the voltage level of the first capacitor C1 is higher than the voltage level of the bit line BL, the charges of the first capacitor C1 are transferred to the bit line BL. Further, the voltage level of the bit line BL rises. Conversely, where the first capacitor C1 and the bit line BL are electrically coupled, if the charge amount of the first capacitor C1 is smaller than the charge amount of the bit line BL, that is, the voltage level of the first capacitor C1 is lower than the voltage level of the bit line BL, the charges of the bit line BL are transferred to the first capacitor C1. In addition, the voltage level of the bit line BL falls.

Further, where the second capacitor C2 and the bit line bar BLB are electrically coupled, if the charge amount of the second capacitor C2 is larger than the charge amount of the bit line bar BLB, that is, the voltage level of the second capacitor C2 is higher than the voltage level of the bit line bar BLB, the charges of the second capacitor C2 are transferred to the bit line bar BLB. Further, the voltage level of the bit line bar BLB rises. Conversely, where the second capacitor C2 and the bit line bar BLB are electrically coupled, if the charge amount of the second capacitor C2 is smaller than the charge amount of the bit line bar BLB, that is, the voltage level of the second capacitor C2 is lower than the voltage level of the bit line bar BLB, the charges of the bit line bar BLB are transferred to the second capacitor C2. In addition, the voltage level of the bit line bar BLB falls.

As a result, since data with different levels are respectively stored in the first and second memory cells 10 and 20 in the write operation, when the word line WL is enabled in the read operation, if the first memory cell 10 raises the voltage level of the bit line BL, the second memory cell 20 lowers the voltage level of the bit line bar BLB. Moreover, since data with different levels are respectively stored in the first and second memory cells 10 and 20 in the write operation, when the word line WL is enabled in the read operation, if the first memory cell 10 lowers the voltage level of the bit line BL, the second memory cell 20 raises the voltage level of the bit line bar BLB.

The sense amplifier 30 senses and amplifies the difference between the voltage levels of the bit line BL and the bit line bar BLB.

If the column select signal Yi is enabled, the bit line BL is electrically coupled with the input/output line IO_L. In addition, the bit line bar BLB is electrically coupled with the input/output line bar IOB_L.

The voltage levels of the bit line BL and the bit line bar BLB amplified by the sense amplifier 30 are transferred to the input/output line IO_L and the input/output line bar IOB_L, respectively, which are electrically coupled with the bit line BL and the bit line bar BLB.

As voltages by the data, or, the charges, stored in the first and second memory cells 10 and 20 are sensed and amplified by the sense amplifier 30 and are then transferred to the input/output line IO_L and the input/output line bar IOB_L, the semiconductor memory apparatus performs the read operation.

In the semiconductor memory apparatus in accordance with an embodiment, a pair of memory cells to store data are selected according to one word line selected by a row-related address and one column select signal selected by a column-related address such that data with different levels are respectively stored in the selected pair of memory cells. In addition, data are outputted from the selected pair of memory cells. In this regard, a sense amplifier which operates in a read operation may perform a normal operation when a voltage difference DV between a bit line and a bit line bar is secured by a predetermined voltage level. In the semiconductor memory apparatus in accordance with an embodiment, between a pair of memory cells which store data with different levels by one word line, if one memory cell raises the voltage level of the bit line, the other memory cell performs an operation of lowering the voltage level of the bit line bar. As a consequence, it is easy to secure the predetermined voltage difference DV between the bit line and the bit line bar, with which a sense amplifier may perform a normal operation. As semiconductor memory apparatuses trend toward miniaturization and low power consumption, the size of a capacitor included in a memory cell is being decreased. In addition, it is difficult to secure the predetermined voltage difference DV with which a sense amplifier operates normally. However, in the semiconductor memory apparatus in accordance with an embodiment, it is possible to secure a voltage difference with which a sense amplifier may operate normally.

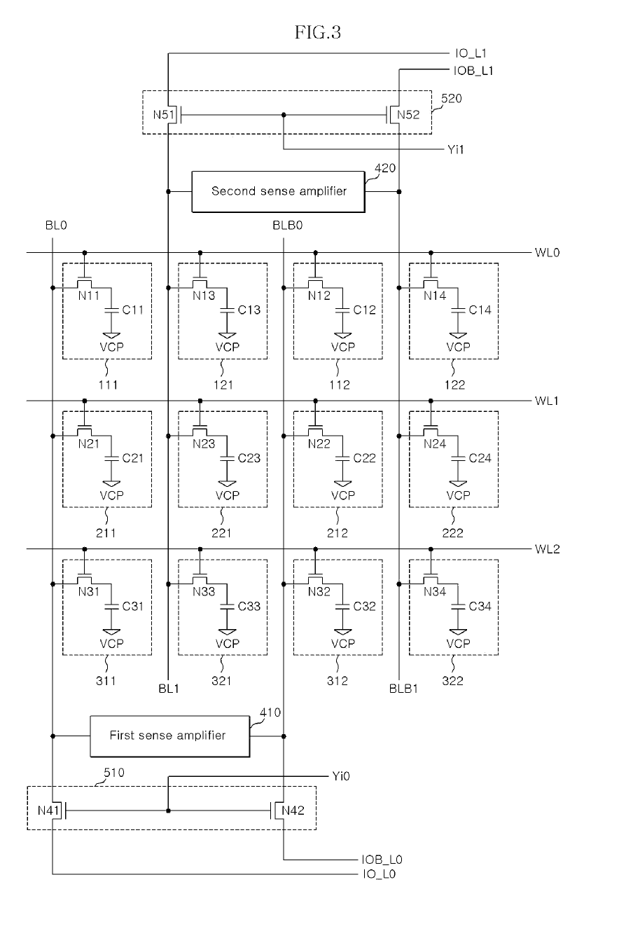

Referring to FIG. 3, a semiconductor memory apparatus in accordance with an embodiment includes first to twelfth memory cells 111, 112, 121, 122, 211, 212, 221, 222, 311, 312, 321 and 322, first and second sense amplifiers 410 and 420, and first and second switching units 510 and 520.

The first memory cell 111 is electrically coupled to a first bit line BL0 and a first word line WL0.

The second memory cell 112 is electrically coupled to a first bit line bar BLB0 and the first word line WL0.

The third memory cell 121 is electrically coupled to a second bit line BL1 and the first word line WL0.

The fourth memory cell 122 is electrically coupled to a second bit line bar BLB1 and the first word line WL0.

The fifth memory cell 211 is electrically coupled to the first bit line BL0 and a second word line WL1.

The sixth memory cell 212 is electrically coupled to the first bit line bar BLB0 and the second word line WL1.

The seventh memory cell 221 is electrically coupled to the second bit line BL1 and the second word line WL1.

The eighth memory cell 222 is electrically coupled to the second bit line bar BLB1 and the second word line WL1.

The ninth memory cell 311 is electrically coupled to the first bit line BL0 and a third word line WL2.

The tenth memory cell 312 is electrically coupled to the first bit line bar BLB0 and the third word line WL2.

The eleventh memory cell 321 is electrically coupled to the second bit line BL1 and the third word line WL2.

The twelfth memory cell 322 is electrically coupled to the second bit line bar BLB1 and the third word line WL2.

The configurations of the first to twelfth memory cells 111, 112, 121, 122, 211, 212, 221, 222, 311, 312, 321 and 322 are the same except that the bit lines and the word lines electrically coupled thereto are different. Therefore, the description of the configuration of the first memory cell 111 will replace the descriptions of the configurations of the other memory cells 112, 121, 122, 211, 212, 221, 222, 311, 312, 321 and 322.

The first memory cell 111 includes a first transistor N11 and a first capacitor C11. The first transistor N11 has the gate to which the first word line WL0 is electrically coupled. The first transistor N11 also has the drain and the source to which the first bit line BL0 and one end of the first capacitor C11 are electrically coupled. The first capacitor C11 has one end to which the first transistor N11 is electrically coupled. The first capacitor C11 also has the other end which is applied with a cell plate voltage VCP. The first switching unit 510 includes a thirteenth transistor N41 and a fourteenth transistor N42. The second switching unit 520 includes a fifteenth transistor N51 and a sixteenth transistor N52.

The first sense amplifier 410 is electrically coupled to the first bit line BL0 and the first bit line bar BLB0. The first sense amplifier also senses and amplifies the voltage difference between the first bit line BL0 and the first bit line bar BLB0.

The second sense amplifier 420 is electrically coupled to the second bit line BL1 and the second bit line bar BLB1. The second sense amplifier 420 also senses and amplifies the voltage difference between the second bit line BL1 and the second bit line bar BLB1.

The first switching unit 510 electrically couples or decouples the first bit line BL0 and a first input/output line IO_L0 and electrically couples or decouples the first bit line bar BLB0 and a first input/output line bar IOB_L0 in response to a first column select signal Yi0. For example, if the first column select signal Yi0 is enabled, the first switching unit 510 electrically couples the first bit line BL0 and the first input/output line IO_L0 and electrically couples the first bit line bar BLB0 and the first input/output line bar IOB_L0. If the first column select signal Yi0 is disabled, the first switching unit 510 electrically decouples the first bit line BL0 and the first input/output line IO_L0 and electrically decouples the first bit line bar BLB0 and the first input/output line bar IOB_L0.

The second switching unit 520 electrically couples or decouples the second bit line BL1 and a second input/output line IO_L1 and electrically couples or decouples the second bit line bar BLB1 and a second input/output line bar IOB_L1 in response to a second column select signal Yi1. For instance, if the second column select signal Yi1 is enabled, the second switching unit 520 electrically couples the second bit line BL1 and the second input/output line IO_L1 and electrically couples the second bit line bar BLB1 and the second input/output line bar IOB_L1. If the second column select signal Yi1 is disabled, the second switching unit 520 electrically decouples the second bit line BL1 and the second input/output line IO_L1 and electrically decouples the second bit line bar BLB1 and the second input/output line bar IOB_L1.

Operations of the semiconductor memory apparatus in accordance with the embodiment configured above will be described below.

A write operation, that is, an operation to store data in memory cells will be described with reference to FIG. 3.

Data inputted from an exterior of the semiconductor memory apparatus are stored in a pair of memory cells selected in response to one word line of the first to third word lines WL0, WL1 and WL2 and one column select signal of the first and second column select signals Yi0 and Yi1.

If the first word line WL0 and the first column select signal Yi0 are enabled, the first and second memory cells 111 and 112 are selected.

If the first word line WL0 and the second column select signal Yi1 are enabled, the third and fourth memory cells 121 and 122 are selected.

If the second word line WL1 and the first column select signal Yi0 are enabled, the fifth and sixth memory cells 211 and 212 are selected.

If the second word line WL1 and the second column select signal Yi1 are enabled, the seventh and eighth memory cells 221 and 222 are selected.

If the third word line WL2 and the first column select signal Yi0 are enabled, the ninth and tenth memory cells 311 and 312 are selected.

If the third word line WL2 and the second column select signal Yi1 are enabled, the eleventh and twelfth memory cells 321 and 322 are selected.

Accordingly, a pair of memory cells are selected in response to one word line and one column select signal. In addition, data with different levels are respectively stored in the selected memory cells.

More specifically, where the first word line WL0 and the first column select signal Yi0 are enabled, the first to fourth memory cells 111, 112, 121 and 122 are electrically coupled to the bit lines BL0 and BL1 and the bit line bars BLB0 and BLB1 by the first word line WL0, and the first input/output line IO_L0 and the first input/output bar IOB_L0 are electrically coupled with the first bit line BL0 and the first bit line bar BLB0 by the first column select signal Yi0. The data transferred to the first input/output line IO_L0 and the first input/output bar IOB_L0 in the write operation are stored at different levels in the first memory cell 111 and the second memory cell 112 through the first bit line BL0 and the first bit line bar BLB0.

In a read operation, if one word line of the first to third word lines WL0, WL1 and WL2 is enabled, the memory cells electrically coupled to the enabled word line transfer their data, that is, their charges, to the bit lines BL0 and BL1 and the bit line bars BLB0 and BLB1. The first and second sense amplifiers 410 and 420 sense and amplify voltage differences of the bit lines BL0 and BL1 and the bit line bars BLB0 and BLB1 electrically coupled to them. As the sense amplifiers 410 and 420 sense and amplify the voltage differences, data are outputted to a corresponding input/output line and a corresponding input/output line bar by an enabled column select signal.

If the first word line WL0 is enabled, the first memory cell 111 transfers data, that is, charges, to the first bit line BL0. Further, the second memory cell 112 transfers charges to the first bit line bar BLB0. In addition, the third memory cell 121 transfers charges to the second bit line BL1 and the fourth memory cell 122 transfers charges to the second bit line bar BLB1. The first sense amplifier 410 senses and amplifies the voltage difference of the first bit line BL0 and the first bit line bar BLB0. The second sense amplifier 420 senses and amplifies the voltage difference of the second bit line BL1 and the second bit line bar BLB1. Due to the fact that data are stored at different levels in a pair of memory cells as in the same manner as the semiconductor memory apparatus shown in FIGS. 1 and 2 and each of the first and second sense amplifiers 410 and 420 senses and amplifies the difference of the levels, it is possible to easily secure the voltage difference between a bit line and a bit line bar needed for the sense amplifier to perform a normal operation.

In the same manner described above, if the second word line WL1 is enabled, the fifth memory cell 211 transfers its data to the first bit line BL0. In addition, the sixth memory cell 212 transfers its data to the first bit line bar BLB0. Further, the seventh memory cell 221 transfers its data to the second bit line BL1. Moreover, the eighth memory cell 222 transfers its data to the second bit line bar BLB1. If the third word line WL2 is enabled, the ninth memory cell 311 transfers its data to the first bit line BL0. In addition, the tenth memory cell 312 transfers its data to the first bit line bar BLB0. Further, the eleventh memory cell 321 transfers its data to the second bit line BL1 and the twelfth memory cell 322 transfers its data to the second bit line bar BLB1. The first sense amplifier 410 senses and amplifies the voltage difference of the first bit line BL0 and the first bit line bar BLB0. The second sense amplifier 420 senses and amplifies the voltage difference of the second bit line BL1 and the second bit line bar BLB1.

The data amplified by the first sense amplifier 410 are transferred to the first input/output line IO_L0 and the first input/output line bar IOB_L0 when the first column select signal Yi0 is enabled. The data amplified by the second sense amplifier 420 are transferred to the second input/output line IO_L1 and the second input/output line bar IOB_L1 when the second column select signal Yi1 is enabled.

In the semiconductor memory apparatus in accordance with an embodiment, a pair of memory cells to store data are selected according to one word line selected by a row-related address and one column select signal selected by a column-related address such that data with different levels are respectively stored in the selected pair of memory cells and data are outputted from the selected pair of memory cells. Accordingly, a sense amplifier which operates in a read operation may perform a normal operation when a voltage difference between a bit line and a bit line bar is secured by a predetermined voltage level. In the semiconductor memory apparatus in accordance with an embodiment, between a pair of memory cells which store data with different levels by one word line, if one memory cell raises the voltage level of the bit line, the other memory cell performs an operation of lowering the voltage level of the bit line bar. Consequently, it is easy to secure the predetermined voltage difference between the bit line and the bit line bar with which a sense amplifier may perform a normal operation. As semiconductor memory apparatuses trend toward miniaturization and low power consumption, the size of a capacitor included in a memory cell is being decreased. In addition, it is difficult to secure the predetermined voltage difference with which a sense amplifier operates normally. However, in the semiconductor memory apparatus in accordance with an embodiment, it is possible to secure a voltage difference with which a sense amplifier may operate normally.

Moreover, in the semiconductor memory apparatus in accordance with an embodiment, to make the distances with which a bit line and a bit line bar are electrically coupled to a sense amplifier the same, the positions of a pair of memory cells, that is, a pair of bit lines (a bit line and a bit line bar), selected by one word line and one column select signal may be disposed not to be most adjacent to each other.

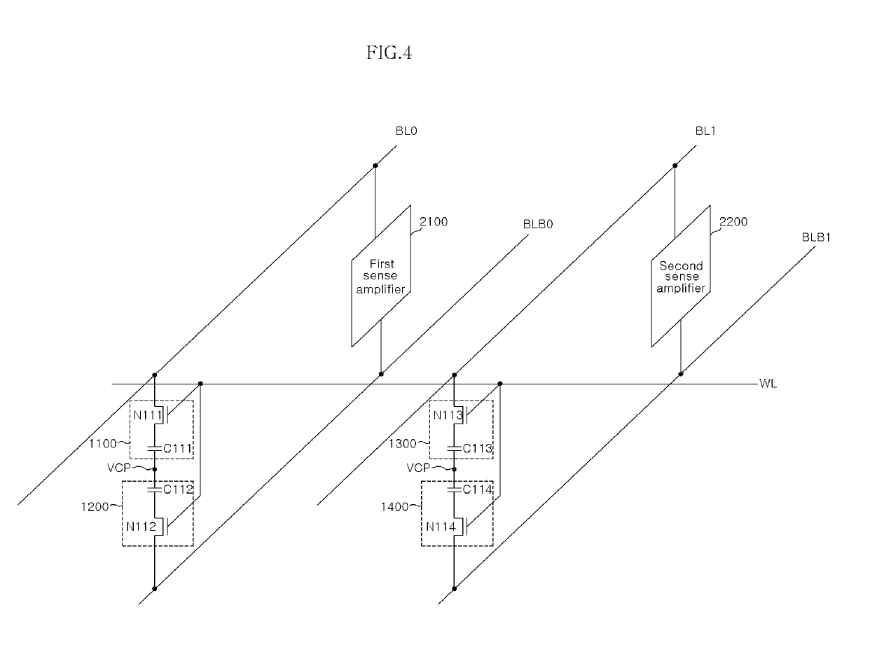

Further, referring FIG. 4, a semiconductor memory apparatus in accordance with an embodiment may be applied to a 3D (three-dimensional) cell stack structure, that is, a vertical memory cell structure.

A first bit line BL0 is disposed over a first bit line bar BLB0.

A second bit line BL1 is disposed over a second bit line bar BLB1.

A first memory cell 1100 and a second memory cell 1200 are electrically coupled between the first bit line BL0 and the first bit line bar BLB0. The first memory cell 1100 is disposed over the second memory cell 1200.

A third memory cell 1300 and a fourth memory cell 1400 are electrically coupled between the second bit line BL1 and the second bit line bar BLB1. The third memory cell 1300 is disposed over the fourth memory cell 1400.

A first sense amplifier 2100 is electrically coupled to the first bit line BL0 and the first bit line bar BLB0.

A second sense amplifier 2200 is electrically coupled to the second bit line BL1 and the second bit line bar BLB1.

The first memory cell 1100 includes a first transistor N111 and a first capacitor C111. The first transistor N111 has the gate to which a word line WL is electrically coupled. The first transistor N111 also has the drain and the source to which the first bit line BL0 and one end of the first capacitor C111 are electrically coupled. The first capacitor C111 has one end to which the first transistor N111 is electrically coupled. The first capacitor C111 also has the other end which is applied with a cell plate voltage VCP.

The second memory cell 1200 includes a second transistor N112 and a second capacitor C112. The second capacitor C112 has one end applied with the cell plate voltage VCP, and the other end to which the second transistor N112 is electrically coupled. The second transistor N112 has the gate to which the word line WL is electrically coupled. The second transistor N112 also has the drain and the source to which the second capacitor C112 and the first bit line bar BLB0 are respectively electrically coupled. The first capacitor C111 is disposed over the second capacitor C112. Further, the cell plate voltage VCP is applied from the node to which one end of the second capacitor C112 and the other end of the first capacitor C111 are electrically coupled.

The third memory cell 1300 includes a third transistor N113 and a third capacitor C113. The third transistor N113 has the gate to which the word line WL is electrically coupled. The third transistor N113 also has the drain and the source to which the second bit line BL1 and one end of the third capacitor C113 are electrically coupled.

The third capacitor C113 has one end to which the third transistor N113 is electrically coupled. The third capacitor C113 also has the other end which is applied with the cell plate voltage VCP.

The fourth memory cell 1400 includes a fourth transistor N114 and a fourth capacitor C114. The fourth capacitor C114 has one end which is applied with the cell plate voltage VCP. The fourth capacitor C114 also has the other end to which the fourth transistor N114 is electrically coupled. The fourth transistor N114 has the gate to which the word line WL is electrically coupled. Further, the fourth transistor N114 also has the drain and the source to which the fourth capacitor C114 and the second bit line bar BLB1 are respectively electrically coupled. The third capacitor C113 is disposed over the fourth capacitor C114. In addition, the cell plate voltage VCP is applied from the node to which one end of the fourth capacitor C114 and the other end of the third capacitor C113 are electrically coupled.

As shown in FIG. 4, memory cells are electrically coupled to a bit line and a bit line bar, respectively, which are electrically coupled to one sense amplifier. In addition, the memory cell electrically coupled to the bit line and the memory cell electrically coupled to the bit line bar are commonly electrically coupled to one word line.

Due to such a configuration, if one word line is enabled, the pair of memory cells, which are respectively electrically coupled to the pair of bit lines electrically coupled to the sense amplifier, are activated. In addition, the data stored in the respective memory cells may be transferred to the bit line and the bit line bar.

The semiconductor memory apparatuses in accordance with the embodiments shown in FIGS. 1 and 3 may also be used in a 3D cell stack structure shown in FIG. 4.

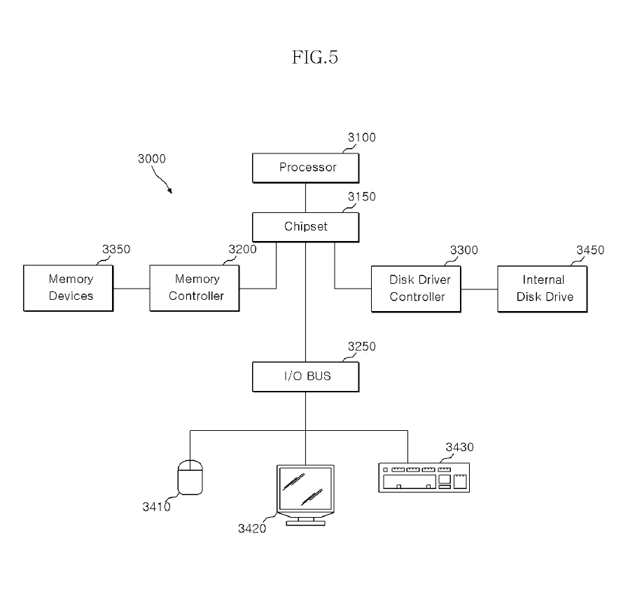

Referring to FIG. 5, a system 3000 may include one or more processors 3100. The processor 3100 may be used individually or in combination with other processors. A chipset 3150 may be operably electrically coupled to the processor 3100. The chipset 3150 is a communication pathway for signals between the processor 3100 and other components of the system 3000. Other components may include a memory controller 3200, an input/output (“I/O”) bus 3250, and a disk drive controller 3300. Depending on the configuration of the system 3000, any one of a number of different signals may be transmitted through the chipset 3150.

The memory controller 3200 may be operably electrically coupled to the chipset 3150. The memory controller 3200 can receive a request provided from the processor 3100 through the chipset 3150. The memory controller 3200 may be operably electrically coupled to one or more memory devices 3350. The memory device 3350 may include the semiconductor memory apparatus described above.

The chipset 3150 may also be electrically coupled to the I/O bus 3250. The I/O bus 3250 may serve as a communication pathway for signals from the chipset 3150 to I/O devices 3410, 3420 and 3430. The I/O devices 3410, 3420 and 3420 may include a mouse 3410, a video display 3420, or a keyboard 3430. The I/O bus 3250 may employ any one of a number of communications protocols to communicate with the I/O devices 3410, 3420, and 3430.

The disk drive controller 3300 may also be operably electrically coupled to the chipset 3350. The disk drive controller 3300 may serve as the communication pathway between the chipset 3150 and one or more internal disk drives 3450. The disk drive controller 3300 and the internal disk drives 1450 may communicate with each other or with the chipset using virtually any type of communication protocol.

While various embodiments have been described above, it will be understood to those skilled in the art that the embodiments described are by way of example only. Accordingly, the semiconductor memory apparatus described should not be limited based on the described embodiments.

What is claimed is:

1. A semiconductor memory apparatus comprising:
a first memory cell electrically coupled to a word line and a bit line;
a second memory cell electrically coupled to the word line and a bit line bar;
a sense amplifier electrically coupled to the bit line and the bit line bar; and
a switching unit configured to electrically couple the bit line and the bit line bar to an input/output line and an input/output line bar in response to a column select signal.

2. The semiconductor memory apparatus according to claim 1, wherein the sense amplifier senses and amplifies a voltage difference of the bit line and the bit line bar.

3. The semiconductor memory apparatus according to claim 1, wherein the switching unit electrically couples the bit line to the input/output line and electrically couples the bit line bar to the input/output line bar when the column select signal is enabled.

4. The semiconductor memory apparatus according to claim 1,
wherein the first memory cell is transferred with charges of the bit line or transfers its charges to the bit line when the word line is enabled, and
wherein the second memory cell is transferred with charges of the bit line bar or transfers its charges to the bit line bar when the word line is enabled.

5. The semiconductor memory apparatus according to claim 2, wherein, when the sense amplifier senses and amplifies the voltage difference of the bit line and the bit line bar, raises a voltage level of one of the bit line and the bit line bar, and lowers a voltage level of the other of the bit line and the bit line bar.

6. The semiconductor memory apparatus according to claim 3, wherein the input/output line and the input/output line bar transfer data with different levels.

7. A semiconductor memory apparatus comprising:
a first memory cell including a first capacitor electrically coupled to a first bit line when a word line is enabled;
a second memory cell including a second capacitor electrically coupled to a first bit line bar when the word line is enabled;
a third memory cell including a third capacitor electrically coupled to a second bit line when the word line is enabled;
a fourth memory cell including a fourth capacitor electrically coupled to a second bit line bar when the word line is enabled;
a first sense amplifier electrically coupled to the first bit line and the first bit line bar;
a second sense amplifier electrically coupled to the second bit line and the second bit line bar;
a first switching unit configured to electrically couple the first bit line and a first input/output line and electrically couple the first bit line bar and a first input/output line bar in response to a first column select signal; and
a second switching unit configured to electrically couple the second bit line and a second input/output line and electrically couple the second bit line bar and a second input/output line bar in response to a second column select signal.

8. The semiconductor memory apparatus according to claim 7, wherein each of the first to fourth memory cells include a transistor having a gate to which the word line is electrically coupled, and a source and a drain which are respectively electrically coupled to a corresponding bit line and a corresponding capacitor to which the transistor is electrically coupled.

9. The semiconductor memory apparatus according to claim 7, wherein, when each of the first and second sense amplifiers senses and amplifies a voltage difference of a corresponding bit line and a corresponding bit line bar to which the sense amplifier is electrically coupled, the sense amplifier raises a voltage of one of the bit line and the bit line bar and lowers a voltage of the other of the bit line and the bit line bar.

10. The semiconductor memory apparatus according to claim 7,
wherein the first bit line and the first bit line bar transfer data with different levels,
wherein the first input/output line and the first input/output line bar transfer data with different levels,
to wherein the second bit line and the second bit line bar transfer data with different levels, and
wherein the second input/output line and the second input/output line bar transfer data with different levels.

11. The semiconductor memory apparatus according to claim 7, wherein the second bit line, the first bit line bar and the second bit line bar are sequentially disposed on one side of the first bit line.

12. A semiconductor memory apparatus comprising:
a plurality of memory cells electrically coupled to a word line;
a plurality of bit lines electrically coupled to the plurality of memory cells;
a switching unit configured to electrically couple a pair of bit lines of the plurality of bit lines with a pair of input/output lines in response to a column select signal; and
a sense amplifier configured to sense and amplify a voltage difference of the pair of bit lines,
wherein a pair of memory cells are selected among the plurality of memory cells in response to the word line and the column select signal, different data are stored in the selected pair of memory cells, and the pair of memory cells are configured to output different data.

13. The semiconductor memory apparatus according to claim 12, wherein, if high level data is stored in one of the pair of memory cells in response to the word line and the column select signal, low level data is stored in the other of the pair of memory cells, and if one of the pair of memory cells outputs high level data, the other of the pair of memory cells outputs low level data.

14. The semiconductor memory apparatus according to claim 13, wherein the selected pair of memory cells are respectively electrically coupled to the pair of input/output lines, and are electrically coupled to the sense amplifier.

15. The semiconductor memory apparatus according to claim 12, wherein the sense amplifier raises a voltage level of a bit line a lowers a voltage level of the bit line bar when the voltage level of the bit line is higher than the voltage level of the bit line bar.

16. The semiconductor memory apparatus according to claim 12, wherein the sense amplifier lowers a voltage level of the bit line and raises the voltage level of the bit line bar when the voltage level of the bit line is lower than the voltage level of the bit line bar.

17. The semiconductor memory apparatus according to claim 12, wherein the switching unit electrically couples the bit line and the input/output line when the column select signal is enabled.

18. The semiconductor memory apparatus according to claim 12, wherein the switching unit electrically couples the bit line bar and the input/output line bar when the column select signal is enabled.

19. The semiconductor memory apparatus according to claim 12, wherein the switching unit electrically decouples the bit line and the input/output line when the column select signal is disabled.

20. The semiconductor memory apparatus according to claim 12, wherein the switching unit electrically decouples the bit line bar and the input/output line bar when the column select signal is disabled.
